(19) United States
(12) Patent Application Publication
(10) Pub. No.: US 2012/0188716 A1
(43) Pub. Date: Jul. 26, 2012

(54) HEAT DISSIPATION SYSTEM

(75) Inventors: RUI WANG, Shenzhen City (CN); ZHI-JIANG YAO, Shenzhen City (CN); LI-FU XU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/186,760

(22) Filed: Jul. 20, 2011

(30) Foreign Application Priority Data
Jan. 26, 2011 (CN) 201110028513.X

(51) Int. Cl. H05K 7/20

(52) U.S. Cl. 361/697

(57) ABSTRACT

A heat dissipation system includes a base plate, a side plate perpendicularly to the base plate, a motherboard attached on the base plate, a first fan, and a second fan fixed on the side plate facing to the heat sink. The motherboard has a first heat source and a second heat source mounted thereon, a heat sink positioned on the first heat source, and a fan bracket mounted on the heat sink. The first fan is positioned on the fan bracket. A rotating axis of the first fan is perpendicular to that of the second fan.

### BACKGROUND

1. Technical Field

The disclosure generally relates to a heat dissipation system, and especially to a heat dissipation system for improving heat dissipation efficiency of multiple heat sources in a computer system.

2. Description of Related Art

A small form factor (SFF) is a computer form factor designed to minimize the spatial volume of a desktop computer. A typical SFF includes a CPU fan and a system fan in a computer case. A plurality of mass storage devices (hard disc driver, optical disc driver) is positioned in the computer case. A heat sink is mounted on the CPU to remove heat, and the CPU fan is fixed on the heat sink to blow airflow through the heat sink. The temperature of the airflow increases by removing the heat generated by the CPU as it passes through the heat sink. The heated airflow is then exhausted from the computer case by the system fan. However, the typical SFF heat dissipation system may be a side-flow type with the fan disposed at a side of the heat sink and plurality of heat pipes fixed on the heat sink. The typical SFF heat dissipation system can only dissipate heat for the single CPU and needs to use heat pipes, which are not efficient and increases the cost.

Therefore there is a room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a heat dissipation system.

FIG. 2 is an exploded, isometric view of the embodiment of the heat sink, the fan bracket and the first fan in FIG. 1.

FIG. 3 is an assembled view of the embodiment of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

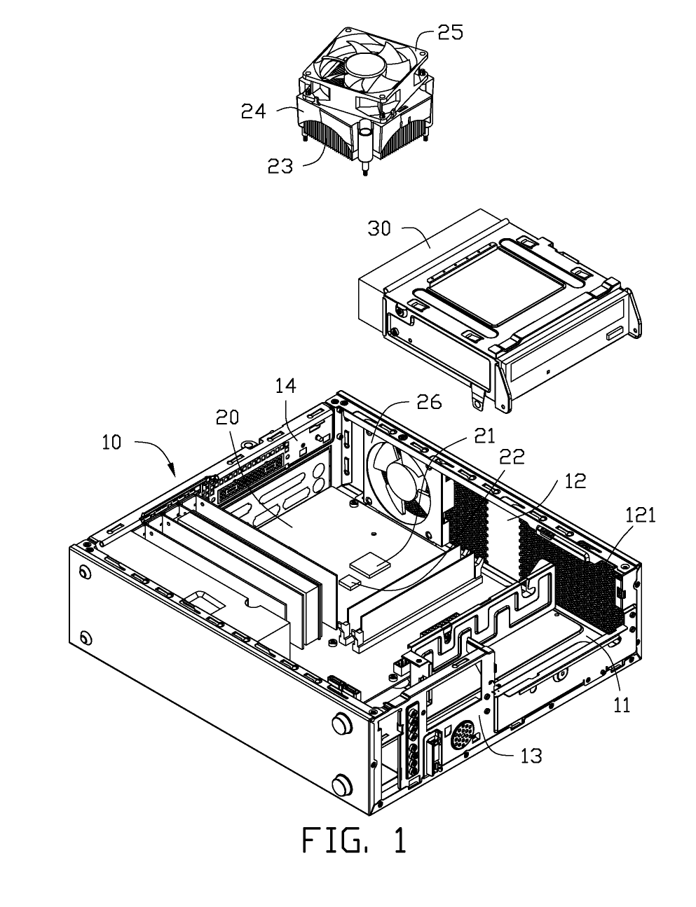

Referring to FIG. 1, an embodiment of a heat dissipation system includes a computer case 10. The computer case 10 includes a base plate 11, a side plate 12, a front plate 13 and a back plate 14. The side plate 12, the front plate 13 and the back plate 14 are perpendicular to the base plate 11.

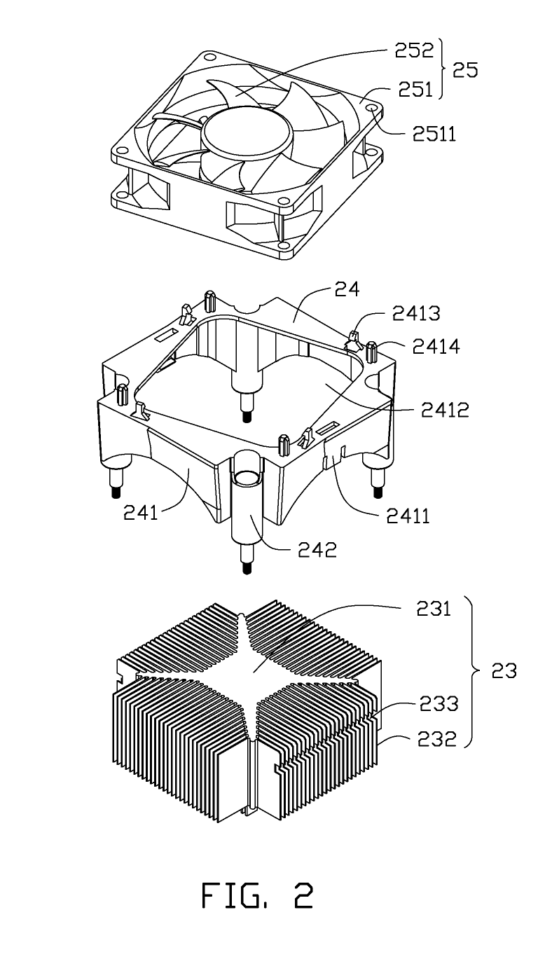

Referring to FIG. 2, the base plate 11 includes a motherboard 20 positioned thereon adjacent to the back plate 14. The motherboard 20 includes a first heat source 21, mounted thereon, and a heat sink 23, positioned on the first heat source 21. A fan bracket 24 is positioned on the heat sink 23 and a first fan 25 is positioned on the fan bracket 24. The motherboard 20 includes a second heat source mounted beside the first heat source 21. The heat sink 23 includes a contact portion 231 for contacting with the first heat source 21 and a plurality of parallel fins 232 that radially extend from the contact portion 231.

Two slots 233 are defined on two opposite sides of the plurality of parallel fins 232. The fan bracket 24 includes a frame 241 and four support legs 242 on corners of the frame 241. Two clamp portions 2411 are defined on two opposite sides of the frame 241 corresponding to the slots 233. The clamp portions 2411 are locked in the corresponding slots 233 to fix the fan bracket 24 on the heat sink 23. The support legs 242 are fixed in the corresponding securing holes (not shown) on the motherboard 20 to fix the heat sink 23 on the motherboard 20. An air outlet opening 2412 is defined on a top plate of the frame 241 for directing airflow from the first fan 25 toward the heat sink 23. Four clasps 2413 and protrusion portions 2414 are defined on the corners of the frame 241 adjacent to the air outlet opening 2412.

The first fan 25 includes a shell 251 and a plurality of fan blades 252. The rotating axis of the first fan 25 is perpendicular to the motherboard 20. A plurality of fixing holes 2511 are defined on corners of a top plate and a bottom plate of the shell 251. The protrusion portions 2414 pass through the corresponding fixing holes 2511. The clasps 2413 clamp edges of the top plate and the bottom plate of the shell 251 to fix the first fan 25 on the fan bracket 24.

A second fan 26 is fixed on the side plate 12 facing to the heat sink 23. A rotating axis of the second fan 26 is parallel to the motherboard 20. The base plate 11 includes a drive device 30 mounted beside the motherboard 20. The drive device 30 is adjacent to the front plate 13. A plurality of air inlet holes 121 are defined on the side plate 12. Cool air from outside is able to flow through an air inlet opening of the first fan 25 via the plurality of air inlet holes 121 and the drive device 30. In one embodiment, the first heat source 21 is a CPU; the second heat source 22 is a voltage regulating chip; and the drive device 30 is an optical disc drive.

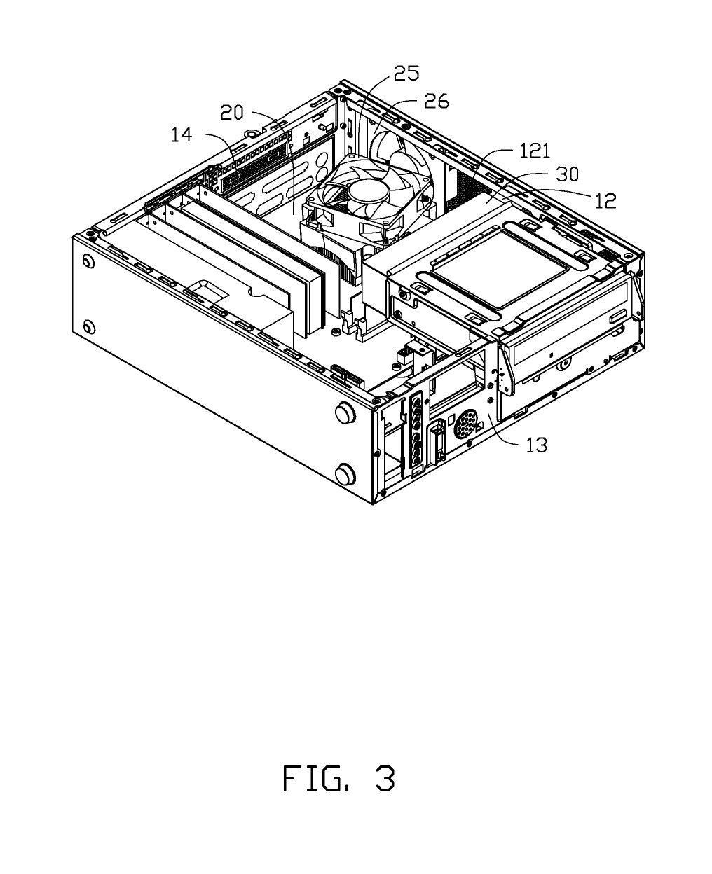

Referring to FIG. 3, in use, the first fan 25 and the second fan 26 rotate to work. The cool air from outside is drawn into the computer case 10 via the plurality of air inlet holes 121 and flows through the drive device 30. The cool air displaces the warm air from around the drive device 30 and flows through the air inlet opening of the first fan 25. The speed of the cool air is accelerated when passing through the first fan 25. The cool air displaces the warm air around the heat sink 23 and flows through the second heat source 22. The warm air from the heat sink 23 and the second heat source 22 is exhausted from the computer case 10 with the second fan 26.

The heat dissipation system is a down-flow type with the first fan 25 disposed on top of the heat sink 23. The rotating axis of the first fan 25 is perpendicular to that of the second fan 26. An air path (not shown) is defined between the plurality of air inlet holes 121 and the back plate 14. The air path directs airflow toward the heat sink 23 via the drive device 30 and the first fan 25. The air path directs airflow out of the computer case 10 via the second fan 26. The heat dissipation system can dissipate heat from the heat sink 23 and the second heat source 22 at the same time. And heat pipes in the typical heat dissipation system are not needed. Therefore heat dissipation efficiency is improved and cost is largely decreased.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation system comprising:
a base plate;
a side plate perpendicularly to the base plate;
a motherboard, attached on the base plate; the motherboard has a first heat source and a second heat source mounted thereon, a heat sink positioned on the first heat source, and a fan bracket mounted on the heat sink;
a first fan positioned on the fan bracket; and
a second fan fixed on the side plate facing to the heat sink; wherein a rotating axis of the first fan is perpendicular to that of the second fan.

2. The heat dissipation system of claim 1, wherein the heat sink comprises a contact portion and a plurality of parallel fins that radially extend from the contact portion.

3. The heat dissipation system of claim 2, wherein two slots are defined on two opposite sides of the plurality of parallel fins; the fan bracket comprises a frame defining two clamp portions on two opposite sides of the frame; and the two clamp portions are locked in the two slots to fix the fan bracket on the heat sink.

4. The heat dissipation system of claim 3, wherein the fan bracket further comprises four support legs on corners of the frame; and the four support legs are fixed in four securing holes on the motherboard to fix the heat sink on the motherboard.

5. The heat dissipation system of claim 3, wherein an air outlet opening is defined on a top plate of the frame; and the first fan is adapted to dissipate heat for the heat sink via the air outlet opening.

6. The heat dissipation system of claim 3, wherein the first fan comprises a shell and a plurality of fan blades; and the rotating axis of the first fan is perpendicular to the motherboard.

7. The heat dissipation system of claim 6, wherein four clasps and protrusion portions are defined on corners of the frame; a plurality of fixing holes are defined on corners of a top plate and a bottom plate of the shell; the protrusion portions are adapted to pass through the corresponding fixing holes; and the four clasps are adapted to clamp edges of the top plate and the bottom plate of the shell to fix the first fan on the fan bracket.

8. The heat dissipation system of claim 1, further comprising a front plate and a back plate perpendicular to the base plate; the motherboard is adjacent to the back plate; the base plate comprises a drive device mounted thereon beside the motherboard; and the drive device is adjacent to the front plate.

9. The heat dissipation system of claim 8, wherein the first heat source is a CPU; the second heat source is a voltage regulating chip; and the drive device is an optical disc drive.

10. The heat dissipation system of claim 8, wherein a plurality of air inlet holes are defined on the side plate; an air path is defined between the plurality of air inlet holes and the back plate; the air path is adapted to direct airflow toward the heat sink via the drive device and the first fan; and the air path is adapted to direct airflow out of the heat dissipation system via the second fan.

11. A heat dissipation system comprising:
a base plate;
a side plate perpendicularly to the base plate and a front plate;
a back plate perpendicularly to the side plate;
a motherboard, attached on the base plate adjacent to the back plate; the motherboard has a first heat source and a second heat source mounted thereon, a heat sink positioned on the first heat source, and a fan bracket mounted on the heat sink;
a first fan positioned on the fan bracket;
a drive device, mounted on the base plate adjacent to the front plate; and
a second fan fixed on the side plate facing to the heat sink; wherein a rotating axis of the first fan is perpendicular to that of the second fan; and the first fan is adapted to direct airflow from outside and the drive device toward the heat sink and the second heat source and out of the computer case via the second fan.

12. The heat dissipation system of claim 11, wherein the heat sink comprises a contact portion and a plurality of parallel fins that radially extend from the contact portion.

13. The heat dissipation system of claim 12, wherein two slots are defined on two opposite sides of the plurality of parallel fins; the fan bracket comprises a frame defining two clamp portions on two opposite sides of the frame; and the two clamp portions are locked in the corresponding slots to fix the fan bracket on the heat sink.

14. The heat dissipation system of claim 13, wherein the fan bracket further comprises four support legs on corners of the frame; and the four support legs are fixed in the corresponding securing holes on the motherboard to fix the heat sink on the motherboard.

15. The heat dissipation system of claim 13, wherein an air outlet opening is defined on a top plate of the frame; and the first fan is adapted to dissipate heat for the heat sink via the air outlet opening.

16. The heat dissipation system of claim 13, wherein the first fan comprises a shell and a rotatable fan blade module; and the rotating axis of the first fan is perpendicular to the motherboard.

17. The heat dissipation system of claim 16, wherein four clasps and protrusion portions are defined on corners of the frame; a plurality of fixing holes are defined on corners of a top plate and a bottom plate of the shell; the protrusion portions are adapted to pass through the corresponding fixing holes; and the four clasps are adapted to clamp edges of the top plate and the bottom plate of the shell to fix the first fan on the fan bracket.

18. The heat dissipation system of claim 11, wherein the first heat source is a CPU; the second heat source is a voltage regulating chip; and the drive device is an optical disc drive.

19. The heat dissipation system of claim 11, wherein a plurality of air inlet holes are defined on the side plate; an air path is defined between the plurality of air inlet holes and the back plate; the air path is adapted to direct airflow toward the heat sink via the drive device and the first fan; and the air path is adapted to direct airflow out of the heat dissipation system via the second fan.
